(19) United States
(12) Patent Application Publication
(10) Pub. No.: US 2025/0176108 A1
(43) Pub. Date: May 29, 2025

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventors: Sangyun Lee, Suwon-si (KR); Dong Keun Lee, Suwon-si (KR); Taehong Min, Suwon-si (KR); Sanghoon Kim, Suwon-si (KR)

(73) Assignee: SAMSUNG ELECTRO-MECHANICS CO., LTD., Suwon-si (KR)

(21) Appl. No.: 18/890,314

(22) Filed: Sep. 19, 2024

(30) Foreign Application Priority Data
Nov. 24, 2023 (KR) 10-2023-0166032

(51) Int. Cl. H05K 1/11; H05K 3/40

(52) U.S. Cl. CPC H05K 1/117; H05K 3/4007

(57) ABSTRACT

A printed circuit board according to an embodiment includes a first insulating layer, a pad portion disposed on the first insulating layer, a connection portion disposed on the pad portion and including a protruding portion and a first recess portion disposed inside the protruding portion, and a second insulating layer disposed on a part of the connection portion and exposing a part of the connection portion, wherein a height of the first recess portion of the connection portion from the first insulating layer is higher than a second height of the second insulating layer disposed on a side of the connection portion.

### CROSS-REFERENCE TO RELATED APPLICATION

This application claims priority to and the benefit of Korean Patent Application No. 10-2023-0166032 filed in the Korean Intellectual Property Office on Nov. 24, 2023, the entire contents of which are incorporated herein by reference.

### BACKGROUND

### 1. Field

The present disclosure relates to a printed circuit board and a manufacturing method thereof.

### 2. Description of the Related Art

As electronic devices in the IT field, including mobile phones, become smaller, the size of the metal posts formed on printed circuit boards on which electronic components are mounted is also becoming smaller.

As the size of the metal post of the printed circuit board decreases, the adherence between the metal post of a printed circuit board and a semiconductor chip mounted on the printed circuit board may decrease.

### SUMMARY

The present disclosure attempts to provide a printed circuit board and a manufacturing method thereof capable of improving the contact characteristics of a connection portion connected to a pad portion of the printed circuit board.

However, embodiments of the present disclosure are not limited to those mentioned above, and may be variously extended in the scope of the technical ideas included in the present disclosure.

A printed circuit board according to an embodiment includes: a first insulating layer; a pad portion disposed on the first insulating layer; a connection portion disposed on the pad portion and including a protruding portion and a first recess portion disposed inside the protruding portion; and a second insulating layer disposed on a part of the connection portion and exposing a part of the connection portion, wherein a height of the first recess portion of the connection portion from the first insulating layer is higher than a height of the second insulating layer disposed on a side of the connection portion.

The recess portion of the connection portion may protrude above the second insulating layer.

The connection portion may further include a second recess portion disposed along an edge of the protruding portion.

The protruding portion may surround the first recess portion, and the second recess portion may surround the protruding portion.

A third height of the second recess portion from the first insulating layer may be higher than the second height of the second insulating layer.

An outer planar shape of the protruding portion of the connection portion and an outer planar shape of the first recess portion may be substantially the same.

The outer planar shape of the protruding portion of the connection portion and the outer planar shape of the first recess portion may be substantially circular.

The outer planar shape of the protruding portion of the connection portion and the outer planar shape of the first recess portion may be different from each other.

The outer planar shape of the protruding portion of the connection portion may be substantially circular, and the outer planar shape of the first recess portion may be square.

The outer planar shape of the first recess portion may be oval.

The height of the first recess portion may decrease from the protruding portion to the center of the connection portion.

The height of the first recess portion may be the lowest height of the first recess portion.

A manufacturing method of a printed circuit board according to an embodiment includes: forming a pad portion on a first insulating layer; forming a first photosensitive film having a first hole overlapping the pad portion on the pad portion; stacking a metal layer on the first hole of the first photosensitive film; forming a second photosensitive film having a second hole overlapping a part of the metal layer; and processing the metal layer to form a connection portion including a protruding portion and a first recess portion disposed inside the protruding portion.

The second photosensitive film may be formed after removing the first photosensitive film.

The second hole of the second photosensitive film may correspond to the protruding portion of the connection portion.

In the processing of the metal layer, a metal layer may be stacked on the metal layer to fill the second hole.

The connection portion may be formed to further include a second recess portion disposed along an edge of the protruding portion, and the second hole of the second photosensitive film may be formed not to overlap the second recess portion.

The second photosensitive film may be formed on the first photosensitive film, and the width of the second hole of the second photosensitive film may be narrower than the width of the first hole of the first photosensitive film.

In the processing of the metal layer, the metal layer exposed by the second hole in the second photosensitive film may be etched to form the first recess portion.

According to embodiments, a printed circuit board capable of improving the contact characteristics of a connection portion connected to a pad portion of the printed circuit board and a manufacturing method thereof may be provided.

However, embodiments of the present disclosure are not limited to those mentioned above, and may be variously extended in the scope of the technical ideas included in the present disclosure.

### BRIEF DESCRIPTION OF THE DRAWINGS

FIG. 1 is a simplified cross-sectional view of a printed circuit board according to an embodiment.

FIG. 2 is a top plan view of a part of FIG. 1.

FIG. 3 is a top plan view of a part of FIG. 1.

FIG. 4 is a top plan view of a part of FIG. 1.

FIG. 5 to 13 are simplified cross-sectional views showing a manufacturing method of a printed circuit board according to an embodiment.

FIG. 14 is a simplified cross-sectional view of a printed circuit board according to another embodiment.

FIG. 15 is a top plan view of a part of FIG. 14.

FIG. 16 is a top plan view of a part of FIG. 14.

FIG. 17 is a top plan view of a part of FIG. 14.

FIGS. 18 to 25 are simplified cross-sectional views showing a manufacturing method of a printed circuit board according to another embodiment.

### DETAILED DESCRIPTION

Hereinafter, the present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

The accompanying drawings are intended only to facilitate an understanding of the embodiments disclosed in this specification, and it is to be understood that the technical ideas disclosed herein are not limited by the accompanying drawings and include all modifications, equivalents, or substitutions that are within the range of the ideas and technology of the present disclosure.

Size and thickness of each constituent element in the drawings are arbitrarily illustrated for better understanding and ease of description, the following embodiments are not limited thereto. In the drawings, the thickness of layers, films, panels, regions, etc., are exaggerated for clarity. In the drawings, the thickness of some layers and regions may be exaggerated for ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” in a direction opposite to gravity.

In addition, unless explicitly described to the contrary, the word “comprise”, and variations such as “comprises” or “comprising”, will be understood to imply the inclusion of stated elements but not the exclusion of any other elements.

In addition, the phrase “on a plane” means a view from a position above the object (e.g., from the top), and the phrase “on a cross-section” means a view of a cross-section of the object which is vertically cut from the side.

Throughout the specification, the term “connected” does not mean only that two or more constituent components are directly connected, but may also mean that two or more constituent components are indirectly connected through another constituent component, that two or more components are electrically connected as well as physically connected, or that two or more constituent components are referred to by different names but are united by location or function.

Hereinafter, various embodiments and variations will be described in detail with reference to the drawings.

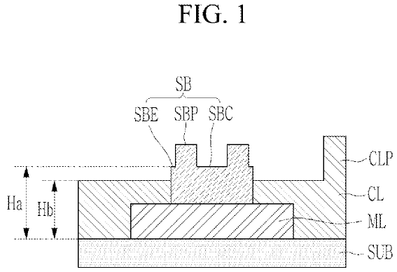

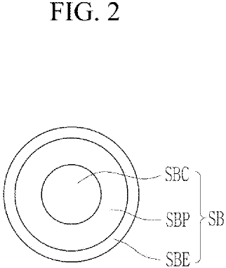

With reference to FIGS. 1 and 2 to 4, a printed circuit board according to an embodiment will be described. FIG. 1 is a simplified cross-sectional view of a printed circuit board according to an embodiment, and FIGS. 2 to 4 are top plan views of a part of FIG. 1.

Referring to FIG. 1, the printed circuit board according to the embodiment may include a first insulating layer SUB, a pad portion ML disposed on the first insulating layer SUB, a connection portion SB disposed on the pad portion ML, and a second insulating layer CL covering a part of the pad portion ML and a part of the connection portion SB.

The connection portion SB may include a protruding portion SBP, a first recess portion SBC inside the protruding portion SBP, and a second recess portion SBE outside the protruding portion SBP.

The connection portion SB may protrude above the second insulating layer CL and be connected to an external device.

The upper surfaces of the first recess portion SBC and the second recess portion SBE, as well as the protruding portion SBP of the connection portion SB, may protrude above the second insulating layer CL.

A height Ha of the first recess portion SBC and the second recess portion SBE of the connection portion SB measured from the first insulating layer SUB may be higher than a second height Hb of the second insulating layer CL disposed on the side of the connection portion SB.

As such, the first recess portion SBC and the second recess portion SBE of the connection portion SB may protrude from the second insulating layer CL such that the height Ha of the first recess portion SBC and the second recess portion SBE of the connection portion SB measured from the first insulating layer SUB is higher than the height Hb of the second insulating layer CL disposed on the side of the connection portion SB. Therefore, during the manufacturing process, the second insulating layer CL may be removed without remaining on the first recess portion SBC and the second recess portion SBE of the connection portion SB. In some embodiments, the first recess SBC and/or second recess SBE are disposed entirely above an upper surface of the second insulating layer CL. For example, the second first recess SBC and second recess SBE are positioned exterior to the second insulating layer CL and do not extend into the second insulating layer CL.

The lower surface of the connection portion SB may contact the pad portion ML to electrically connect the printed circuit board to an external device.

The second insulating layer CL may include an upwardly protruded portion CLP, but the protruded portion CLP may be omitted.

The second insulating layer CL may include solder resist, but the embodiment is not limited thereto.

Although not shown, the pad portion ML may be connected to an additional wiring layer disposed below the first insulating layer SUB or embedded in the first insulating layer SUB through a via formed in the first insulating layer SUB.

Referring to FIGS. 1-2, the outer planar shape formed by the edge of the protruding portion SBP of the connection portion SB of the printed circuit board according to an embodiment may be substantially the same as the outer planar shape formed by the edge of the first recess portion SBC and the outer planar shape formed by the edge of the second recess portion SBE.

The outer planar shape of the protruding portion SBP of the connection portion SB, the outer planar shape of the first recess portion SBC, and the outer planar shape of the second recess portion SBE may have a substantially circular planar shape. In other embodiments, the outer planar shape of the protruding part SBP of the connection portion SB, the outer planar shape of the first recess portion SBC, and the outer planar shape of the second recess portion SBE may be substantially oval.

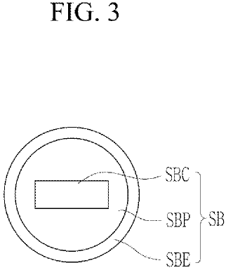

Referring to FIG. 3, the outer edge of the connection portion SB of the printed circuit board according to an embodiment may have a substantially circular outer planar shape, but the first recess portion SBC may have a square outer planar shape, and the second recess portion SBE of the connection portion SB may have a substantially circular outer planar shape.

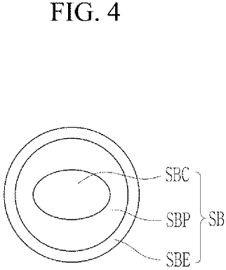

Referring to FIG. 4, the outer edge of the connection portion SB of the printed circuit board according to an embodiment may have a substantially circular outer planar shape, but the first recess portion SBC may have an oval outer planar shape, and the second recess portion SBE of the connection portion SB may have a substantially circular outer planar shape.

The outer planar shapes of the protruding portion SBP, the first recess portion SBC, and the second recess portion SBE of the connection portion SB may be changed in various ways.

The connection portion of the printed circuit board according to the embodiment may include the upwardly protruding portion SBP, the first recess portion SBC inside the protruding portion SBP, and the second recess portion SBE outside the protruding portion SBP. Compared to conventional connection portions, which are generally in the form of a single column that does not include any recesses, the surface area provided by the connection portion SB of the present disclosure upon which a connection may be made is substantially greater.

According to the embodiments described herein, the surface area of the connection portion SB protruding above the surface of the second insulating layer CL of the connection portion SB may be increased, so that the contact area between the external device and the connection portion SB may be relatively larger. Further, it is possible to increase the adhesion between the external device and the connection portion SB by reducing the shear stress between the external device and the connection portion SB, and to reduce the contact resistance between the external device and the connection portion SB to decrease the loss of electrical signals and reduce electrical resistance.

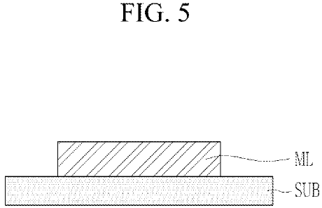

Referring to FIGS. 5 to 13 along with FIGS. 1 to 4, a manufacturing method of a printed circuit board according to an embodiment will be described. FIGS. 5 to 13 are simplified cross-sectional views showing a manufacturing method of a printed circuit board according to an embodiment.

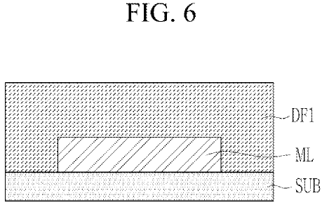

Referring to FIG. 5, the pad portion ML may be formed on the first insulating layer SUB. Referring to FIG. 6, a first photosensitive film DF1 may be stacked on the pad portion ML.

The first photosensitive film DF1 may be photosensitive and may be a dry film, but the embodiment is not limited thereto.

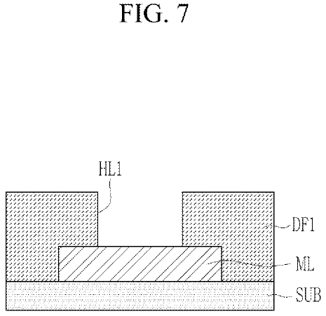

As shown in FIG. 7, a first hole HL1 that at least partially overlaps the pad portion ML may be formed in the first photosensitive film DF1.

The first hole HL1 of a photosensitive film DF may have a pillar shape occupied by the protruding portion SBP, the first recess portion SBC, and the second recess portion SBE of the connection portion SB.

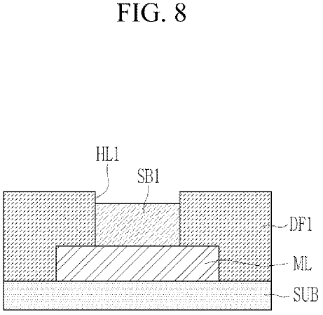

Referring to FIG. 8, a metal layer may be formed in the first hole HL1 of the first photosensitive film DF1 to form a first portion SB1 of the connection portion SB.

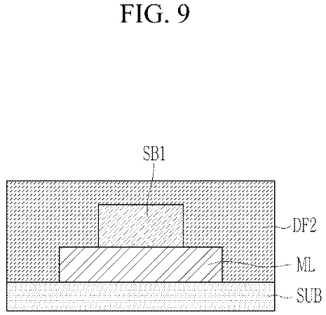

Referring to FIG. 9, the first photosensitive film DF1 may be removed, and a second photosensitive film DF2 may be stacked on the first portion SB1 of the connection portion SB.

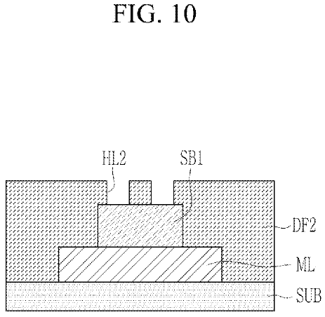

Referring to FIG. 10, a second hole HL2 may be formed in the second photosensitive film DF2. The second hole HL2 may be formed in an area where the protruding portion SBP of the connection portion SB is formed, and the planar shape of the second hole HL2 may be the same as the planar shape of the protruding portion SBP of the connection portion SB. In some embodiments, the second hole HL2 may have a shape defined by two concentric circles.

In FIG. 10, the middle portion of the first portion SB1 of the connection portion SB that does not overlap the second hole HL2 of the second photosensitive film DF2 may correspond to the first recess portion SBC of the connection portion SB. An edge portion of the second photosensitive film DF2 that does not overlap the second hole HL2 may correspond to the second recess portion SBE of the connection portion SB.

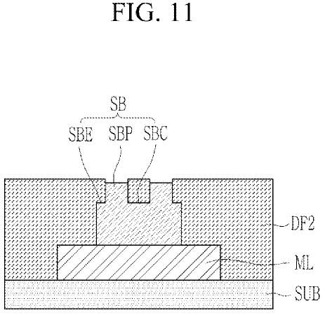

Referring to FIG. 11, a metal layer may be formed on the first portion SB1 of the connection portion SB overlapping the second hole HL2 of the second photosensitive film DF2, to form the protruding portion SBP of the connection portion SB disposed inside the second hole HL2 of the second photosensitive film DF2. Thus, the connection portion SB including the protruding portion SBP, the first recess portion SBC, and the second recess portion SBE may be formed.

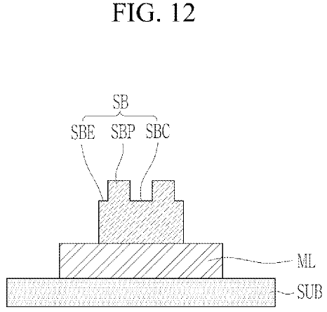

Referring to FIG. 12, the second photosensitive film DF2 may be removed.

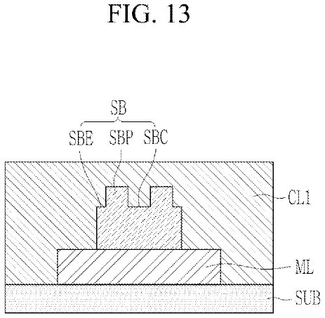

Referring to FIG. 13, an insulating layer CL1 may be stacked on the connection portion SB.

Thereafter, a part of the insulating layer CL1 may be removed to form a second insulating layer CL exposing the protruding portion SBP, the first recess portion SBC, and the second recess portion SBE of the connection portion SB, as shown in, for example, FIG. 1. In some embodiments, the printed circuit board of FIG. 1 may be formed according to the steps outlined in FIGS. 5-13 and as described above.

The height Ha of the first recess portion SBC and the second recess portion SBE of the connection portion SB measured from the first insulating layer SUB may be higher than the height Hb of the second insulating layer CL disposed on the side of the connection portion SB. Accordingly, all, or at least a substantial portion, of the insulating layer CL1, shown in FIG. 13, which covers the first recess portion SBC, the second recess portion SBE, and/or the protruding portion SBP of the connection portion SB may be removed.

According to the manufacturing method of the printed circuit board according to the embodiment, the connection portion SB may be formed to include the protruding portion SBP, the first recess portion SBC inside the protruding portion SBP, and the second recess portion SBE outside the protruding portion SBP. As discussed above, when compared to a conventional connection portion that is in the form of a single column (e.g., that does not include any recesses), the surface area the connection portion SB of the present disclosure protrudes above the second insulating layer CL and may be substantially increased.

Therefore, according to the embodiment, the surfaces of the protruding portion SBP of the connection portion SB protruding above the surface of the second insulating layer CL, the first recess portion SBC and the second recess portion SBE of the connection portion SB may be increased, so that the contact area between the external device and the connection portion SB may be relatively greater. Accordingly, it is possible to increase the adhesion between the external device and the connection portion SB by reducing the shear stress between the external device and the connection portion SB, and to reduce the contact resistance between the external device and the connection portion SB to decrease the loss of electrical signals and reduce electrical resistance.

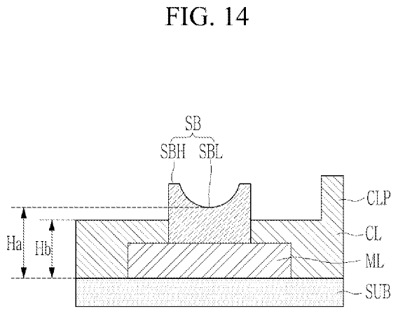

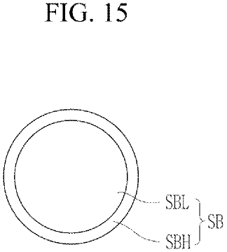

Referring to FIGS. 14 and 15 to 17, a printed circuit board according to an embodiment will be described. FIG. 14 is a simplified cross-sectional view of a printed circuit board according to another embodiment, and FIGS. 15 to 17 are top plan views of a part of FIG. 14.

Referring to FIG. 14, the printed circuit board according to the embodiment is similar to the printed circuit board according to the embodiment previously shown and described in relation to FIGS. 1-13.

Referring to FIG. 14, the printed circuit board according to the embodiment may include the first insulating layer SUB, the pad portion ML disposed on the first insulating layer SUB, the connection portion SB disposed on the pad portion ML, and the second insulating layer CL covering a part of the pad portion ML and a part of the connection portion SB.

The connection portion SB may include the recess portion SBL formed at the center and having a height Hb, and the protruding portion SBH surrounding the outside of the recess portion SBL and having a height greater than the height Hb of the recess portion SBL.

The height Hb of the recess portion SBL of the connection portion SB may be the lowest at the center of the connection portion SB and may gradually become higher toward the protruding portion SBH of the connection portion SB. For example, the recess portion SBL may be generally semispherical in shape.

The connection portion SB may protrude above the second insulating layer CL and be connected to an external device.

The upper surface of the recess portion SBL of the connection portion SB, as well as the protruding portion SBH of the connection portion SB, may protrude above the second insulating layer CL.

A height Ha of the recess portion SBL, which may be measured from the point of the recess portion SBL closest to the first insulating layer SUB, may be greater than a height Hb of the second insulating layer CL disposed on the side of the connection portion SB. In some embodiments, the recess portion SBL is disposed entirely above an upper surface of the second insulating layer CL. For example, the recess portion SBL is positioned exterior to the second insulating layer CL and does not extend into the second insulating layer CL.

As such, the recess portion SBL of the connection portion SB may protrude from the second insulating layer CL so that the third height Ha, which is the lowest height of the recess portion SBL of the connection portion SB measured from the first insulating layer SUB is higher than the second height Hb of the second insulating layer CL disposed on the side of the connection portion SB. Therefore, during the manufacturing process, the second insulating layer CL may be completely removed without remaining on the recess portion SBL of the connection portion SB.

The lower surface of the connection portion SB may contact the pad portion ML to electrically connect the printed circuit board to an external device.

The second insulating layer CL may include an upwardly protruded portion CLP, but the protruded portion CLP may be omitted.

The second insulating layer CL may include solder resist, but the embodiment is not limited thereto.

Although not shown, the pad portion ML may be connected to an additional wiring layer disposed below the first insulating layer SUB or embedded in the first insulating layer SUB through a via formed in the first insulating layer SUB.

Referring to FIGS. 14-15, the protruding portion SBH and the recess portion SBL of the connection portion SB of the printed circuit board according to an embodiment may have substantially the same planar shape.

The edges of the protruding portion SBH and the edges of the recess portion SBL of the connection portion SB may have a substantially circular outer planar shape. In some embodiments, the edges of the protruding portion SBH and the edges of the recess portion SBL of the connection portion SB may have a substantially oval outer planar shape.

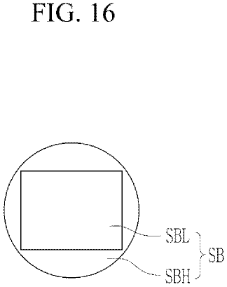

Referring to FIG. 16, the edge of the connection portion SB of the printed circuit board according to an embodiment may have a substantially circular outer planar shape, but the edge of the recess portion SBL of the connection portion SB may have a generally square outer planar shape.

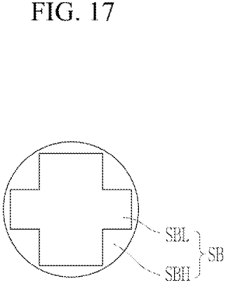

Referring to FIG. 17, the edge of the connection portion SB of the printed circuit board according to an embodiment may have a substantially circular outer planar shape, but the edge of the recess portion SBL of the connection portion SB may have a polygonal outer planar shape.

The outer planar shapes of the protruding portion SBH and the recess portion SBL of the connection portion SB may be changed in various ways.

The connection portion SB of the printed circuit board according to the embodiment may include the protruding portion SBH and the recess portion SBL positioned interior to the protruding portion SBH. When compared to a conventional connection portion being in the form of a single column that does not include the any recess, the surface area the connection portion SB protrudes above the second insulating layer CL, as shown and described in relation to FIGS. 14-15 may be increased.

Therefore, according to the embodiment, the surface area of the connection portion SB protruding above the surface of the second insulating layer CL of the connection portion SB may be increased, so that the contact area between the external device and the connection portion SB may be relatively larger. Therefore, it is possible to increase the adhesion between the external device and the connection portion SB by reducing the shear stress between the external device and the connection portion SB, and to reduce the contact resistance between the external device and the connection portion SB to decrease the loss of electrical signals and reduce electrical resistance.

Many features of the printed circuit board according to the embodiment described above with reference to FIGS. 1-4 are all applicable to the printed circuit board according to the embodiments shown in FIGS. 14-17.

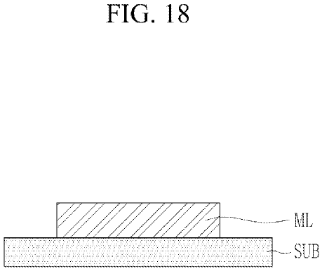

Referring to FIGS. 18 to 25 along with FIGS. 14 to 17, a manufacturing method of a printed circuit board according to an embodiment will be described. FIGS. 18 to 25 are simplified cross-sectional views showing a manufacturing method of a printed circuit board according to another embodiment.

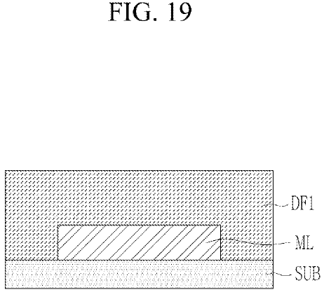

Referring to FIG. 18, the pad portion ML may be formed on the first insulating layer SUB. Referring to FIG. 19, the first photosensitive film DF1 may be applied on the pad portion ML.

The first photosensitive film DF1 may be photosensitive and may be a dry film, but the embodiment is not limited thereto.

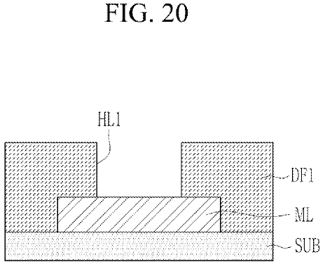

As shown in FIG. 20, the first hole HL1, which at least partially overlaps the pad portion ML may be formed in the first photosensitive film DF1.

The first hole HL1 of the photosensitive film DF may have a pillar shape occupied by both the protruding portion SBH and the recess portion SBL of the connection portion SB.

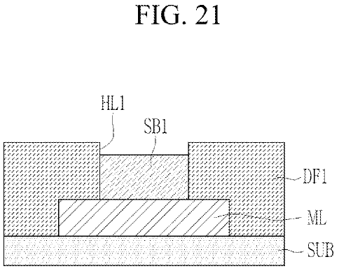

Referring to FIG. 21, a metal layer is formed in the first hole HL1 of the first photosensitive film DF1 to form the first portion SB1 of the connection portion SB.

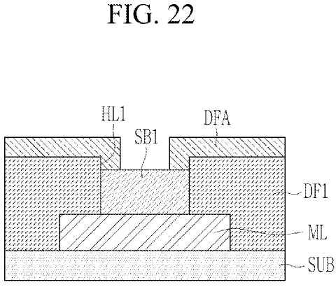

Referring to FIG. 22, a second photosensitive film DFA may be formed on the first photosensitive film DF1, and the second hole HL2 exposing a part of the first portion SB1 of the connection portion SB may be formed.

The second hole HL2 may be formed in an area where the recess portion SBL of the connection portion SB is formed, and the planar shape of the second hole HL2 may be the same as the planar shape of the recess portion SBL of the connection portion SB. The size of the second hole HL2 may be smaller than the size of the first hole HL1.

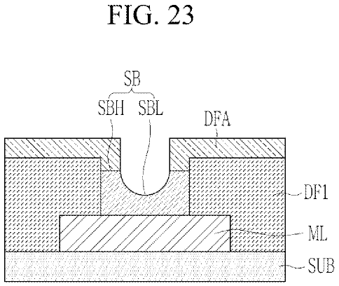

Referring to FIG. 23, by etching the first portion SB1 of the connection portion SB exposed by the second hole HL2 of the second photosensitive film DFA, the recess portion SBL of the connection portion SB may be formed. Thus, the connection portion SB including the recess portion SBL disposed at the center and having a low height, and the protruding portion SBH surrounding the outside of the recess portion SBL and having a high height may be formed.

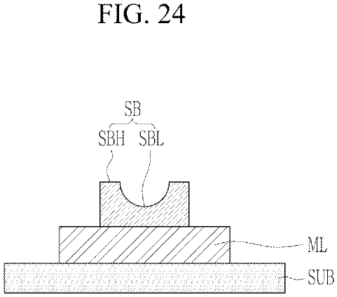

Referring to FIG. 24, the second photosensitive film DFA may be removed.

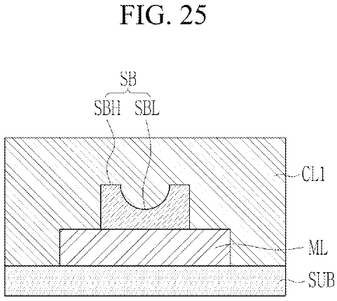

Referring to FIG. 25, the insulating layer CL1 may be stacked on the connection portion SB.

Thereafter, a part of the insulating layer CL1 may be removed to form the second insulating layer CL exposing the surfaces of the protruding portion SBH and the recess portion SBL of the connection portion SB, thus the printed circuit board of FIG. 14 may be formed.

At this time, the third height Haa, which is the lowest height of the recess portion SBL of the connection portion SB measured from the first insulating layer SUB, may be higher than the second height Hb of the second insulating layer CL disposed on the side of the connection portion SB. Accordingly, all of the insulating layer CL1 on the recess portion SBL of the connection portion SB can be removed.

According to the manufacturing method of the printed circuit board according to the embodiment, the connection portion SB may be formed to include the protruding portion SBH and the recess portion SBL inside the protruding portion SBH. As discussed above, forming the connection portion SB in accordance with the method illustrated and described in FIGS. 18-25 may result in the connection portion SB having increased surface are when compared to conventional connection portions.

Therefore, according to the embodiment, the surface area of the protruding portion SBH of the connection portion SB protruding above the surface of the second insulating layer CL of the connection portion SB and the recess portion SBL may be widened, so that the contact area between the external device and the connection portion SB may be relatively wide. Accordingly, it is possible to increase the adhesion between the external device and the connection portion SB by reducing the shear stress between the external device and the connection portion SB, and to reduce the contact resistance between the external device and the connection portion SB to decrease the loss of electrical signals and reduce electrical resistance.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

### Description of Symbols

ML: Pad portion
SB: Connection portion
SBC, SBE, SBL: Recess portion
SBP, SBH: Protruding portion
SUB, CL: Insulating layer

What is claimed is:

1. A printed circuit board, comprising:
a first insulating layer;
a pad portion disposed on the first insulating layer;
a connection portion disposed on the pad portion and including a protruding portion and a first recess portion disposed inside the protruding portion; and
a second insulating layer disposed on the pad portion and exposing a part of the connection portion,
wherein a height of the first recess portion of the connection portion as measured from an upper surface of the first insulating layer is greater than a height of the second insulating layer, as measured from an upper surface of the first insulating layer and disposed on a side of the connection portion.

2. The printed circuit board of claim 1, wherein
the recess portion of the connection portion is positioned above the second insulating layer.

3. The printed circuit board of claim 2, wherein
the connection portion further comprises a second recess portion disposed along an edge of the protruding portion.

4. The printed circuit board of claim 3, wherein
the protruding portion surrounds the first recess portion, and the second recess portion surrounds the protruding portion.

5. The printed circuit board of claim 3, wherein
a height of the second recess portion as measured from the first insulating layer is higher than the height of the second insulating layer.

6. The printed circuit board of claim 5, wherein
an outer planar shape of the protruding portion of the connection portion and an outer planar shape of the first recess portion are substantially the same.

7. The printed circuit board of claim 6, wherein
the outer planar shape of the protruding portion of the connection portion and the outer planar shape of the first recess portion are substantially circular.

8. The printed circuit board of claim 5, wherein
the outer planar shape of the protruding portion of the connection portion and an outer planar shape of the first recess portion are different from each other.

9. The printed circuit board of claim 8, wherein
the outer planar shape of the protruding portion of the connection portion is substantially circular, and the outer planar shape of the first recess portion is square.

10. The printed circuit board of claim 8, wherein
the outer planar shape of the protruding portion of the connection portion is substantially circular, and the outer planar shape of the first recess portion is oval.

11. The printed circuit board of claim 2, wherein
the height of the first recess portion decreases from the protruding portion to the center of the connection portion.

12. The printed circuit board of claim 11, wherein
the height of the first recess portion is the lowest height of the first recess portion.

13. The printed circuit board of claim 12, wherein
the protruding portion surrounds the first recess portion.

14. A manufacturing method of a printed circuit board, comprising:
forming a pad portion on a first insulating layer;
forming a first photosensitive film having a first hole overlapping the pad portion on the pad portion;
stacking a metal layer on the first hole of the first photosensitive film;
forming a second photosensitive film having a second hole overlapping a part of the metal layer; and
processing the metal layer to form a connection portion including a protruding portion and a first recess portion disposed inside the protruding portion.

15. The manufacturing method of the printed circuit board of claim 14, wherein
the second photosensitive film is formed after removing the first photosensitive film.

16. The manufacturing method of the printed circuit board of claim 15, wherein
the second hole of the second photosensitive film is formed to correspond to the protruding portion of the connection portion.

17. The manufacturing method of the printed circuit board of claim 16, wherein
in the processing of the metal layer, a metal layer is deposited on the metal layer to fill the second hole.

18. The manufacturing method of the printed circuit board of claim 17, wherein
the connection portion is formed to further include a second recess portion disposed along an edge of the protruding portion,
and the second hole of the second photosensitive film is formed without overlapping the second recess portion.

19. The manufacturing method of the printed circuit board of claim 14, wherein
the second photosensitive film is formed on the first photosensitive film,
and the width of the second hole of the second photosensitive film is narrower than the width of the first hole of the first photosensitive film.

20. The manufacturing method of the printed circuit board of claim 19, wherein
in the processing of the metal layer, the metal layer exposed by the second hole in the second photosensitive film is etched to form the first recess portion.
